(19) United States
(12) Patent Application Publication
(10) Pub. No.: US 2009/0004763 A1
(43) Pub. Date: Jan. 1, 2009

(54) LASER CRYSTALLIZATION METHOD AND CRYSTALLIZATION APPARATUS

(76) Inventors: Takashi Ono, Hadano-shi (JP); Masakiyo Matsumura, Kamakura-shi (JP); Kazurumi Azuma, Yokohama-shi (JP); Tomoya Kato, Mobara-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/145,826

(22) Filed: Jun. 25, 2008

(30) Foreign Application Priority Data
Jun. 28, 2007 (JP) 2007-170678

(51) Int. Cl. H01L 21/00; B05C 11/00

(52) U.S. Cl. 438/7; 118/708; 257/E21.001

(57) ABSTRACT

The present invention discloses a laser crystallization method and crystallization apparatus using a high-accuracy substrate height control mechanism. There is provided a laser crystallization method includes obtaining a first pulse laser beam having an inverse-peak-pattern light intensity distribution formed by a phase shifter, and irradiating a thin film disposed on a substrate with the first pulse laser beam, thereby melting and crystallizing the thin film, the method includes selecting a desired one of reflected light components of a second laser beam by using a polarizing element disposed on an optical path of the second laser beam when illuminating, with the second laser beam, an first pulse laser beam irradiation position of the thin film, correcting a height of the substrate to a predetermined height by detecting the selected reflected light component, and irradiating the first pulse laser beam to the thin film having the corrected height.

### CROSS-REFERENCE TO RELATED APPLICATIONS

This application is based upon and claims the benefit of priority from prior Japanese Patent Application No. 2007-170678, filed Jun. 28, 2007, the entire contents of which are incorporated herein by reference.

### BACKGROUND OF THE INVENTION

1. Field of the Invention

The present invention relates to a laser crystallization method and crystallization apparatus and, more particularly, to a laser crystallization method and crystallization apparatus for crystallizing a film to be crystallized by controlling the height of the film with a high accuracy and irradiating the film with a laser beam.

2. Description of the Related Art

A thin film transistor (TFT) formed in a semiconductor film such as a silicon film disposed on a substrate such as a glass substrate having a large area is used as, e.g., a switching element of a liquid crystal display device.

The semiconductor film used to form the thin film transistor is crystallized by using, e.g., the laser crystallization technique that melts and crystallizes a non-single-crystal semiconductor film by using a high-energy, short-pulse laser beam.

The crystal grain size of a semiconductor film obtained by using the conventional laser crystallization apparatus is as small as 1 μm or less. This limits the performance of a TFT because the TFT is fabricated in a region including the grain boundary.

To improve the performance of a TFT, it is required to fabricate a high-quality semiconductor film having large crystal grains. To meet this requirement, a technique that performs crystallization by irradiating a phase-modulated excimer laser beam, i.e., phase modulated excimer laser annealing (PMELA), is particularly attracting attention among various laser crystallization techniques. In the PMELA technique, a phase modulating element such as a phase shifter modulates the phase of an excimer laser beam so as to adjust the excimer laser beam to a predetermined light intensity distribution. The excimer laser beam is irradiated on a non-single-crystal semiconductor film, such as an amorphous silicon film, disposed on a glass substrate, thereby melting and crystallizing the irradiated area of the semiconductor film. The presently developed PMELA technique melts and crystallizes about a few mm square region by one excimer laser beam irradiation, thereby forming a high-quality crystallized silicon film containing relatively uniform crystal grains having a grain size of about a few μm to 5 μm (e.g., see “Amplitude and Phase Modulated Excimer-Laser Melt-Regrowth Method of Silicon Thin-Films—A New Growth Method of 2-D Position—Controlled Large-Grains—” published by Kohki Inoue, Mitsuru Nakata, and Masakiyo Matsumura in Journal of the Institute of Electronics, Information and Communication Engineers, Vol. J85-C, No. 8, pp. 624-629, 2002). A TFT formed in a crystallized silicon film by this method reportedly has stable electrical characteristics.

To obtain a crystallized semiconductor film having larger and relatively uniform crystal grains by the PMELA technique, it is important to more precisely control the crystallization temperature to make the temperature gradient gentler. To this end, crystallization must be performed by accurately controlling the height of a substrate to be processed to an imaging position of a crystallizing laser beam. Jpn. Pat. Appln. KOKAI Publication No. 2006-40949 has disclosed a crystallization apparatus having a substrate height measuring system. The disclosed substrate height measuring system shares a part of an optical system, i.e., an imaging optical system, with a crystallization laser optical system. That is, substrate height measuring light is set to almost perpendicularly incident on a substrate to be processed so as to be coaxial with the crystallizing laser beam. The reflected measuring light from the substrate is detected by a pinhole or photodetector disposed in a position optically conjugated with the substrate with respect to the imaging optical system. The substrate height is adjusted to a position where the intensity of the detected reflected light is maximized or a position where the reflected image is clearest, thereby adjusting the surface height of the substrate to be processed with the imaging position of the crystallizing laser beam.

### BRIEF SUMMARY OF THE INVENTION

The above subject is solved by laser crystallization methods and crystallization apparatus according to the present invention.

According to one aspect of the present invention, there is provided a laser crystallization method comprising: obtaining a first pulse laser beam having an inverse-peak-pattern light intensity distribution by transmitting light through a phase shifter; and irradiating a thin film disposed on a substrate with the first pulse laser beam, thereby melting and crystallizing the thin film, the method comprising: selecting a desired one of a plurality of reflected light components of a second laser beam by using a polarizing element disposed on an optical path of the second laser beam when illuminating, with the second laser beam, an irradiation position of the thin film to be irradiated with the first pulse laser beam and detecting the second laser beam reflected by the thin film; correcting a height of the substrate to a predetermined height by detecting the selected reflected light component of the second laser beam; and irradiating the first pulse laser beam to the irradiation position of the thin film on the substrate having the corrected height.

According to another aspect of the present invention, there is provided a laser crystallization apparatus comprising a crystallization optical system configured to melt and crystallize an irradiation region of a thin film disposed on a substrate by irradiating the thin film with a first laser beam having an inverse-peak-pattern light intensity distribution, the apparatus comprising: a substrate height correcting mechanism, the mechanism including: a light emitting unit disposed outside an optical path of the first laser beam, and configured to emit a second laser beam which illuminates the irradiation region of the thin film to be irradiated with the first laser beam; a light receiving unit configured to detect the second laser beam reflected by the thin film, and convert the detected second laser beam into an electrical signal; and a polarizing element disposed on an optical path of the second laser beam and outside the optical path of the first laser beam, and configured to select a desired one of a plurality of reflected light components of the second laser beam by adjusting a polarizing direction.

According to another aspect of the present invention, there is provided a laser crystallization apparatus comprising a crystallization optical system configured to melt and crystallize an irradiation region of a thin film disposed on a substrate by irradiating the thin film with a first laser beam having an inverse-peak-pattern light intensity distribution, the apparatus comprising: a substrate height measuring mechanism; and a substrate stage mechanism, the substrate height measuring mechanism including: a light emitting unit disposed outside an optical path of the first laser beam, and configured to emit a second laser beam which illuminates the irradiation region of the thin film to be irradiated with the first laser beam; a light receiving unit configured to detect the second laser beam reflected by the thin film, and convert the detected second laser beam into an electrical signal; and a polarizing element disposed on an optical path of the second laser beam and outside the optical path of the first laser beam, and configured to select a desired one of a plurality of reflected light components of the second laser beam by adjusting a polarizing direction, and the substrate stage mechanism including: a substrate mounting stage independently movable in three directions perpendicular to each other, and including a plurality of driving elements for movement in a height direction; and a stage driver configured to control the movement of the substrate mounting stage.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a view showing an example of a laser crystallization apparatus according to the first embodiment of the present invention;

FIG. 2 is a view showing an example of the sectional structure of a substrate to be processed used in embodiments of the present invention;

FIG. 3A is a sectional view of a substrate to be processed having a multilayered structure for explaining reflected light when the substrate is irradiated with a measuring laser beam containing random polarizing components;

FIG. 3B is a graph showing an example of the light intensity distribution of the reflected light in a case shown in FIG. 3A;

FIG. 4 is a graph showing an example of the reflected light intensity distribution of the measuring laser beam when a polarizing element is used;

FIG. 5A is a sectional view of a substrate to be processed for explaining a method of correcting the deviation of the height of the substrate according to the first embodiment;

FIG. 5B is a graph showing an example of the positional deviation of the reflected light on a light receiving unit in a case shown in FIG. 5A;

FIG. 6 is a flowchart for explaining an example of a laser crystallization method of a semiconductor film according to the first embodiment;

FIG. 7 is a graph showing an example of the light intensity distribution of reflected light according to a modification of the first embodiment;

FIG. 8 is a view showing an example of a laser crystallization apparatus according to the second embodiment of the present invention;

FIGS. 9A and 9B are views showing examples of the arrangement of Z-axis driving elements of a high-accuracy substrate mounting stage according to the second embodiment of the present invention;

FIGS. 10A and 10B are graphs for explaining the relationship between a set value and the actual height in substrate stage height adjustment;

FIG. 11 is a view showing an example of a substrate height controller of the laser crystallization apparatus according to the second embodiment;

FIG. 12 is a flowchart for explaining a laser crystallization method of a semiconductor film according to the second embodiment; and

FIG. 13 is a view showing an example of a laser crystallization apparatus according to the third embodiment of the present invention.

### DETAILED DESCRIPTION OF THE INVENTION

The laser crystallization techniques are required to increase the crystal grain size in a crystallized semiconductor film. To meet this requirement, it is effective to control the temperature gradient gentle of a semiconductor film melted by a crystallizing laser beam having an inverse-peak-pattern light intensity distribution in the PMELA technique. In this case, however, if the height of a semiconductor film to be processed deviates even slightly from an imaging position of a phase shifter, the melt temperature changes. This makes it impossible to well crystallize the film with a high reproducibility. Accordingly, a demand has arisen for determining the height of a substrate to be processed with accuracy higher than the conventional accuracy, e.g., with accuracy of the order of a few tens of nm.

In addition, in a substrate to be processed used in the PMELA technique, the number of layers of a structure including a semiconductor film to be crystallized is more and more increasing. When measuring the surface height of a substrate to be processed having a larger number of layers by using obliquely incident light, the reflected light from the substrate contains not only a reflection component from the outermost surface of the substrate but also reflection components from the interfaces of the individual layers and also contains multiple reflection components between these layers.

A conventional substrate height control method controls the height of a substrate by detecting measuring light, e.g., a visible laser beam, reflected from the substrate, and performing image processing and the like on the reflected light. If, therefore, the reflected light contains a plurality of reflection components, i.e., a plurality of reflection peaks, sufficient height accuracy can no longer be obtained, or even if a high accuracy can be obtained, the image processing requires a long time, and this makes the method unrealistic.

Accordingly, in the PMELA technique, demands have arisen for a method and apparatus for determining the height of the substrate to be processed with a high accuracy, e.g., accuracy of the order of a few tens of nm.

The present invention discloses a laser crystallization method and crystallization apparatus using a high-accuracy substrate height control mechanism which uses an oblique incident height measuring light, e.g., a visible laser beam, and in which a polarizing plate is disposed in the optical path of the height measuring light, in the PMELA technique that melts and crystallizes a semiconductor film, e.g., an amorphous silicon film, by irradiating the film with a crystallizing laser beam, e.g., an excimer laser beam, modulated to a desired light intensity distribution, e.g., an inverse peak pattern, by a phase shifter.

The embodiments of the present invention will be described with reference to the accompanying drawings. The accompanying drawings, which are incorporated in and constitute a part of the specification, illustrate embodiments of the invention, and together with the general description given above and the detailed description of the embodiments given below, serve to explain principles of the invention. Throughout the drawings, corresponding portions are denoted by corresponding reference numerals. The embodiments are only examples, and various changes and modifications can be made without departing from the scope and spirit.

### First Embodiment

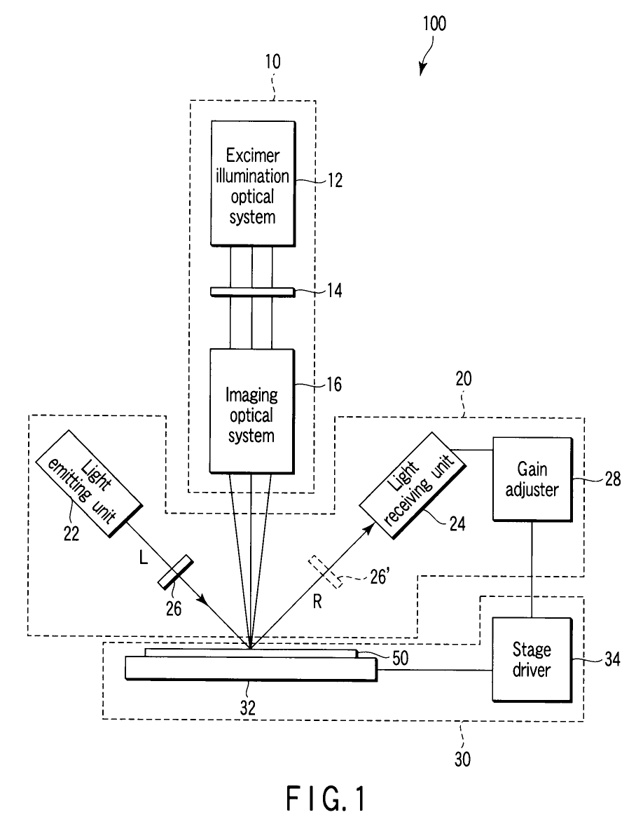

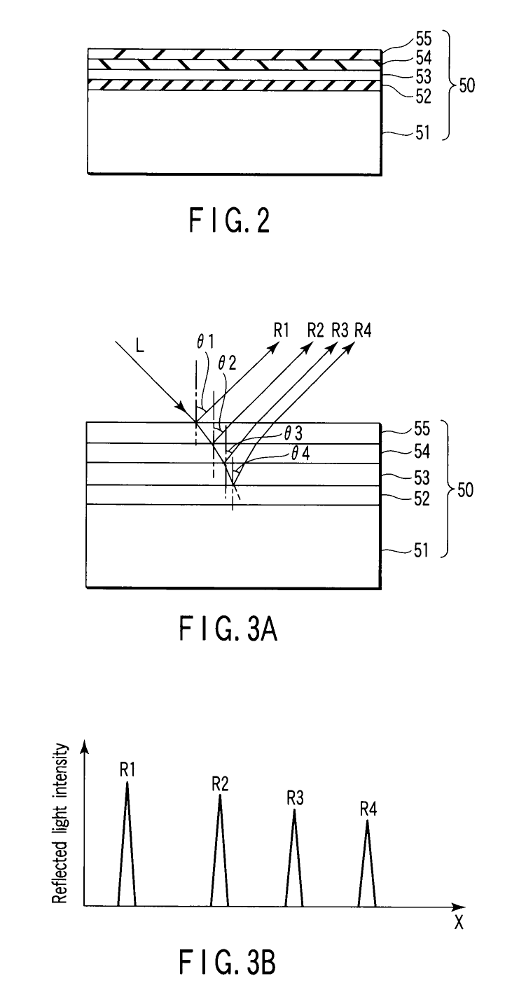

FIG. 1 shows an example of a laser crystallization apparatus according to the first embodiment of the present invention. A laser crystallization apparatus 100 comprises a crystallization optical system 10, substrate height measuring system 20, and stage system 30. The crystallization optical system 10 modulates a crystallizing laser beam, e.g., an excimer laser beam, to a desired light intensity distribution, and irradiates the crystallizing laser beam onto a substrate 50 to be processed placed on a substrate mounting stage 32 of the stage system 30. A semiconductor film 53 (see FIG. 2) disposed on the substrate 50 irradiated with the laser beam is melted and crystallized into a semiconductor film 53 having large crystal grains.

The crystallization optical system 10 includes an excimer illumination optical system 12, phase modulating element 14, and imaging optical system 16.

The excimer illumination optical system 12 adjusts an excimer pulse laser beam emitted from a laser source to a large-area laser beam having a uniform light intensity distribution. As this excimer pulse laser beam, it is possible to use, e.g., a KrF excimer pulse laser beam having a wavelength of 248 nm or an XeCl excimer pulse laser beam having a wavelength of 308 nm. The excimer pulse laser beam is a pulse oscillation type laser beam whose oscillation frequency is, e.g., 100 to 300 Hz, and has a high optical energy of about 1 J/cm² on the substrate 50.

The phase modulating element 14, e.g., a phase shifter, modulates the crystallizing laser beam having a uniform light intensity distribution to a desired light intensity distribution such as an inverse-peak-pattern light intensity distribution. The inverse-peak-pattern light intensity distribution is a light intensity distribution in which the intensity of light transmitted through a phase shifting portion of the phase shifter is almost zero, and the transmitted light intensity increases as the light moves away from the phase shifting portion.

The imaging optical system 16 forms an image of the crystallizing laser beam having a predetermined light intensity distribution on the substrate 50 that is placed in a position optically conjugated with the phase shifter 14. The imaging optical system 16 comprises, e.g., a lens group including calcium fluoride (CaF₂) lenses and/or synthetic quartz lenses. The imaging optical system 16 is, e.g., a long-focus lens having a reduction ratio of 1/5, an NA of 0.13, a resolution of 2 μm, a depth of focus of ±10 μm, and a focal length of 50 to 70 mm.

A thin film such as a thin non-single-crystal semiconductor film on a substrate to be processed on which an image of the pulse laser beam having an inverse-peak-pattern light intensity distribution is to be imaged is melted and gradually cooled to the solidification temperature from a portion corresponding to a minimum-light-intensity portion of the inverse-peak-pattern light intensity distribution during the interrupting period of the pulse laser beam. Consequently, crystals having a large grain size are grown in the lateral direction.

The substrate height measuring system 20 is an oblique light incident system that precisely controls the height of the substrate 50 to an imaging position of the crystallizing laser beam with a high accuracy of the order of, e.g., 10 nm, by accurately detecting the displacement of the position of reflected measuring light. The substrate height measuring system 20 includes a light emitting unit 22, light receiving unit 24, polarizing element 26, and gain adjuster 28. The polarizing element 26 is, e.g., a polarizing plate that determines the polarizing direction by absorbing an electromagnetic wave in a certain polarizing direction. The polarizing element 26 can be disposed in any position in the optical path of the substrate height measuring system 20 where the polarizing element 26 does not interrupt the optical path of the crystallizing laser beam. That is, the polarizing element can be disposed on the incident light side (26), or on the reflected light side (26′). The substrate height measuring system 20 will be explained in more detail later together with a substrate height control method of this embodiment.

The stage system 30 comprises the substrate mounting stage 32 for detachably mounting the substrate 50, and a stage driver 34 for driving the substrate stage by controlling it in the X, Y, and Z directions.

FIG. 2 shows an example of the sectional structure of the substrate 50 to be processed. The substrate 50 is a large-area substrate having dimensions of, e.g., 550 mm×650 mm. As shown in FIG. 2, the substrate 50 to be crystallized generally has a structure in which the semiconductor film 53 (e.g., an amorphous silicon film, polycrystalline silicon film, sputtered silicon film, silicon-germanium film, or dehydrogenated amorphous silicon film) is disposed on a base insulating film 52 on a supporting substrate 51 (e.g., a glass substrate, a plastic substrate, or a semiconductor substrate (wafer) made of silicon or the like), and insulating films 54 and 55 are disposed as cap insulating films on the semiconductor film 53. The semiconductor film 53 is, e.g., a dehydrogenated amorphous silicon film, and has a thickness of, e.g., 50 nm. The base insulating film 52 prevents the diffusion of an unwanted impurity from the supporting substrate 51 into the semiconductor film 53 when crystallizing the semiconductor film 53, and has a thickness of, e.g., 50 nm. The cap insulating films 54 and 55 have a function of storing heat during crystallization, and have a thickness of, e.g., 200 nm. The cap insulating films 54 and 55 increase the crystallization efficiency by using their reflection characteristics and heat absorption characteristics. The first cap insulating film 54 is, e.g., an SiO₂ film, and the second cap insulating film 55 is, e.g., an SiOₓ film (x<2). The SiOₓ film has an ultraviolet ray (excimer pulse laser beam) absorbance and heat storage efficiency higher than those of the SiO₂ film. Accordingly, desired heat storage characteristics can be obtained by adjusting the film thicknesses of the SiOₓ film and SiO₂ film.

The semiconductor film 53 has absorption characteristics to the incidence of the crystallizing pulse laser beam. Therefore, the semiconductor film 53 is heated and melted.

A method of controlling the substrate height with a high accuracy of the order of 10 nm by using the substrate height measuring system 20 of this embodiment will now be explained with reference to FIG. 1.

The light emitting unit 22 of the substrate height measuring system 20 emits a measuring laser beam L to a predetermined area of the substrate 50, and the light receiving unit 24, e.g., a CCD camera, detects reflected light R. The area to be irradiated with the measuring laser beam is, e.g., the central portion of a crystallizing pulse laser beam irradiation position to be crystallized next. The measuring laser beam from the light emitting unit 22 is a visible laser beam or ultraviolet laser beam. For example, the measuring laser beam is preferably an He—Ne laser beam that diverges little when output. As shown in FIG. 1, an incident angle θ (an angle between the incident light and the normal to the surface of the substrate to be processed, see FIG. 3A) to the measuring laser beam irradiation surface (the surface of the substrate 50) is preferably 0°<θ≦75°, and more preferably 45°≦θ≦60° in order to separate reflected light components (to be described later). The measuring laser beam L emitted from the light emitting unit 22 contains random polarizing components. The light receiving unit 24, e.g., a CCD camera, converts the detected reflected light R into an electrical signal. This electrical signal contains position information and light intensity information of the reflected light R on the light receiving surface of the light receiving unit 24. The electrical signal is supplied to the gain adjuster 28. The gain adjuster 28 adjusts the intensity of the reflected light R which changes in accordance with, e.g., the film structure or film thickness of the substrate 50. The gain adjuster 28 generates a height control signal for controlling the substrate height to a desired height by processing the electrical signal obtained by the CCD camera or the like and containing the position information in order to maximize the detected light intensity at a predetermined position of the light receiving surface, and supplies the height control signal to the stage driver 34. The stage driver 34 adjusts the height of the stage by an amount indicated by the substrate height control signal.

FIGS. 3A and 3B are views for explaining the reflected light R when the substrate 50 having the multilayered structure as described above is irradiated with the measuring laser beam L containing the random polarizing components. As shown in FIG. 3A, depending on, e.g., the materials and film thicknesses of the individual layers of the substrate 50, the measuring laser beam L causes reflection on the substrate surface and at the interfaces of these layers, and also causes multiple reflection, interference, and the like between the layers, thereby generating the reflected light R containing multiple reflected light components, e.g., R1 to R4, as shown in FIG. 3A. FIGS. 3A and 3B illustrate only portions of the reflected light components for the sake of descriptive simplicity. The reflected light components R1 to R4 are observed in positions shifted from each other in a direction (to be referred to as the X direction hereinafter, see FIG. 3B) obtained by projecting the reflecting direction of the measuring laser beam L onto the surface of the substrate 50. FIG. 3B is a graph showing examples of the light intensity distributions of the reflected light components R1 to R4. As shown in FIG. 3B, the reflected light components R1 to R4 are detected in different positions in the X direction on the light receiving surface of the light receiving unit 24, and have different light intensities owing to, e.g., absorption by the individual films.

Accordingly, when measuring the height of the substrate 50 by using the measuring laser beam L having the random polarizing components as described above, the reflected light R is composite light of the reflected light components R1, R2, . . . , so the surface height of the substrate 50 is difficult to accurately measure. In other words, if the height of the substrate 50 is measured by simply measuring the reflected light R, a height error depending on the film thickness variations of the individual layers stacked on the base insulating film 52 is produced. This height error causes the crystallizing laser beam transmitted through the phase shifter to irradiate a film to be processed in a position deviated from the imaging position of the crystallizing laser beam. This deviation from the imaging position causes smaller crystal grain size obtained by crystallization. That is, the variation in height of the film caused variation in the crystallized grain size.

Each reflected light component shown in FIGS. 3A and 3B have a unique polarizing component and different polarizing state each other in accordance with, e.g., the film thicknesses and surface (interface) states of the base insulating film 52, semiconductor film 53, and cap insulating films 54 and 55. In addition, since the base insulating film 52, semiconductor film 53, and cap insulating films 54 and 55 have different refractive indices and different reflectances, the reflected light components R1, R2, R3, and R4 respectively have reflection angles θ1, θ2, θ3, and θ4. Furthermore, these reflected light components have different polarizing components. As shown in FIG. 1, therefore, the polarizing element 26 is disposed in the optical path of the substrate height measuring system 20. In the polarizing element 26, a polarizer is set at a right angle to the optical axis of the measuring light and able to rotate around the optical axis as a rotational axis. The polarizing element 26 is rotated around the optical axis and set at an angle at which a desired reflected light component, e.g., R1, from the surface of the substrate 50 is maximally transmitted. This makes it possible to polarize the measuring laser beam L into a laser beam Lₚ practically containing only one polarizing component in a desired direction. Consequently, the use of the polarizing element 26 makes it possible to suppress undesirable reflected light components caused by, e.g., the reflected light from different interfaces and the like, multiple reflection, or interference, and reflected light components within the reflected light component R1 caused by multiple reflection, interference, or the like, and select the desired reflected light component R1. Assume that the reflection angles θ1, θ2, θ3, and θ4 of the reflected light components to the films are respectively 60°, 30°, 25°, and 20°. In this case, the polarizing element 26 is set to intercept reflected light components at reflection angles equal to or smaller than 30°, and the reflected light is received through this polarizing element. This makes it possible to selectively detect the reflected light R1 having the reflection angle θ1 from the surface of the second cap insulating film 55 at a high signal-to-noise ratio.

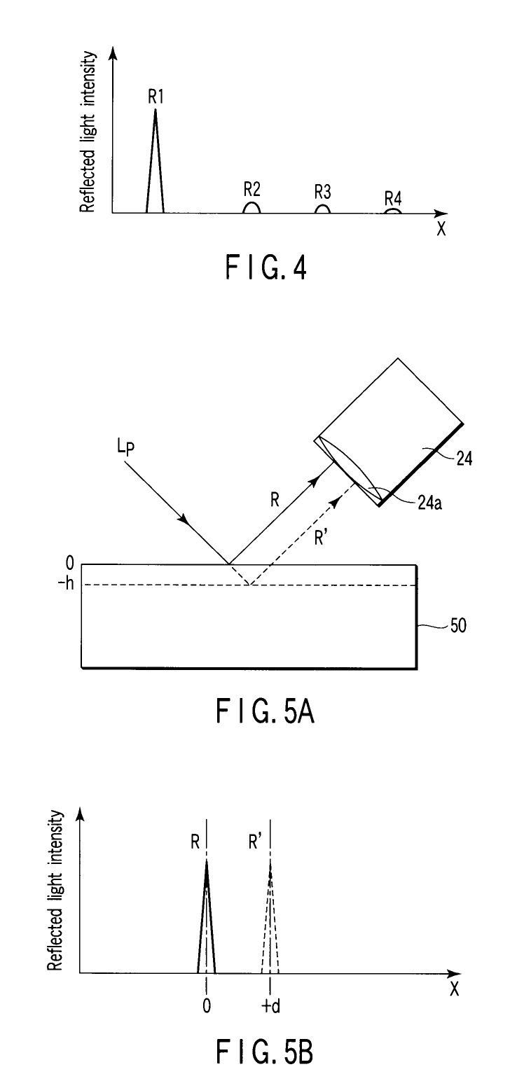

FIG. 4 is a graph for explaining the change in reflected light intensity of the measuring laser beam resulting from the use of the polarizing element. The polarizing element determines a desired polarizing direction by absorbing an electromagnetic wave in a certain polarizing direction. The reflected light intensities of the reflected light components R1 to R4 shown in FIG. 3B change as shown in FIG. 4 when the polarizing element 26 is used. That is, the reflected light intensity of the selected reflected light component R1 hardly attenuates because the ratio of the desired polarizing component is high. However, the intensity of each of the unselected reflected light components R2, R3, and R4 attenuates because the ratio of the desired polarizing component is low. Accordingly, the unselected reflected light components can be eliminated by processing the light intensities according to a threshold value or decreased to be negligible. Note that it is possible to select any arbitrary reflected light, e.g., the reflected light from the surface of the substrate 50 or the reflected light from the interface between the first cap insulating film 54 and semiconductor layer 53 by adjusting the rotation angle of the polarizing element 26. The following explanation will be made by taking the reflected light from the surface of the substrate 50, i.e., the surface of the second cap insulating film 55 as an example. FIG. 1 shows the example in which the polarizing element is disposed on the incident light side (26) of the substrate height measuring system 20. However, the same effect can be obtained by disposing the polarizing element 26′ on the reflected light side as well.

FIGS. 5A and 5B are views for explaining a method of correcting the deviation of the height of the substrate 50. In the substrate height measuring system 20 having the polarizing element 26 disposed to select the desired reflected light component as described above, reflected light R′ to be selected is detected in a position displaced in the X direction on the light receiving surface if the height of the substrate 50 displaces. Assume that the substrate height displaces by −h from a reference position (indicated by “0”) as shown in FIG. 5A. The selected reflected light R′ is detected in a position displaced by +d in the X direction from the reference position “0” on the light receiving surface as shown in FIG. 5B. The light receiving unit 24 converts the light received on the light receiving surface into an electrical signal by using, e.g., a CCD camera. This electrical signal contains information of the position and light intensity on the light receiving surface. The light receiving unit 24 supplies the converted electrical signal to the gain adjuster 28. The gain adjuster 28 adjusts the electrical signal intensity, and generates a control signal for controlling the height of the substrate 50 so as to maximize the light intensity in the reference position on the light receiving surface. The gain adjuster 28 supplies this control signal to the stage system 30. The stage driver 34 of the stage system 30 adjusts the height of the substrate stage 32 in accordance with the substrate height control signal so as to maximize the reflected light intensity in the reference position on the light receiving surface.

As described above, the height of the substrate 50 must be controlled to be of the order of 10 nm. When a height displacement amount h is of the order of 10 nm, a displacement amount d of the reflected light in the X direction on the light receiving surface is also of the order of 10 nm. Since a very small displacement amount like this is difficult to accurately measure, the light receiving unit 24 of this embodiment has a magnifying lens 24a. The magnification of the magnifying lens 24a is, e.g., ×100 to ×1,000. The magnifying lens 24a can magnify the displacement amount of the order of 10 nm to an amount of the order of 1 to 10 μm. A displacement amount of the order of μm can be detected by, e.g., a semiconductor image sensor (CCD camera) and a photodetector using an optical stop such as a slit. This effectively makes it possible to detect and adjust the height displacement of the order of 10 nm of the substrate 50.

The height of the substrate 50 is preferably adjusted each time before the substrate 50 is irradiated with the crystallizing laser beam. If the flatness of the substrate 50 is high, however, the substrate height can also be adjusted before the laser beam is irradiated every several times.

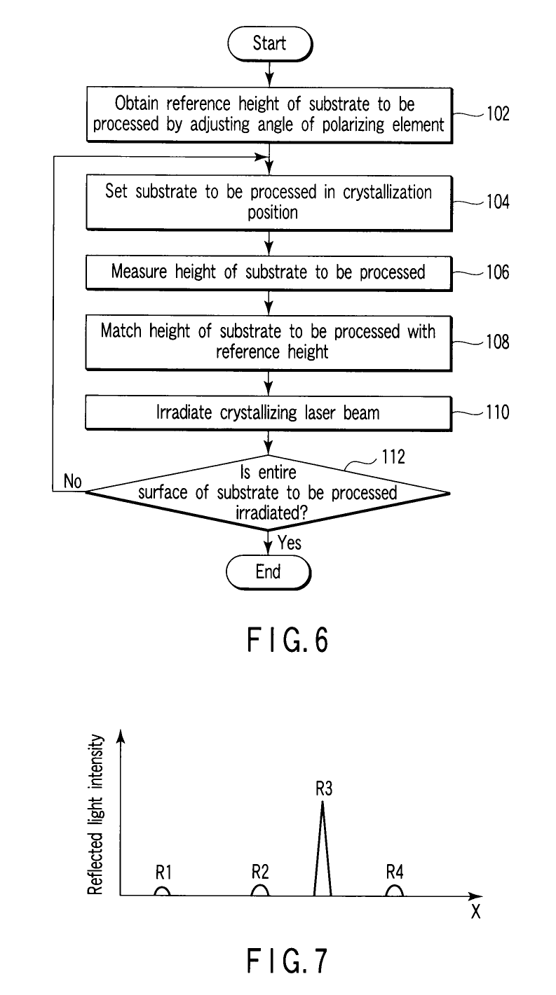

The laser crystallization method of the semiconductor film according to this embodiment will be explained below with reference to a flowchart shown in FIG. 6.

In step 102, a reference substrate height with which the semiconductor film 53 is desirably crystallized is obtained before crystallization of the substrate 50. More specifically, by using the laser crystallization apparatus 100 for use in crystallization, the substrate 50 or a substrate having a structure equal to that of the substrate 50 is illuminated with the substrate height measuring laser beam, and the polarizing element 26 disposed on the optical path of the measuring laser beam is adjusted to select a desired reflected light component, e.g., a component having a maximum light intensity, from reflected light components from the substrate. Then, the position of the detected reflected light on the light receiving unit 24 is measured, and the semiconductor film 53 is crystallized by irradiating the crystallizing laser beam. This crystallization is repeated by changing the height of the substrate. A height at which, for example, the crystal grains of the crystallized semiconductor film 53 are largest is determined as the reference substrate height. That is, a substrate position at this height is the reference substrate height, and is coincide with the imaging position of the crystallizing laser beam modulated to an inverse-peak-pattern light intensity distribution. The detection position of the reflected light on the light receiving unit 24 which corresponds to the reference substrate height is the reference position of the measuring light. Accordingly, the height of the substrate 50 is controlled such that the detection position of the reflected substrate height measuring laser beam matches the reference position of the measuring light immediately before the crystallizing laser beam is irradiated. In this manner, the semiconductor film 53 of the substrate 50 is controlled to match the reference substrate height desirable for crystallization.

In step 104, the substrate 50 is mounted on the substrate stage 32 of the laser crystallization apparatus 100, and set in a predetermined crystallization position by the stage driver 34.

In step 106, the substrate height measuring optical system 20 measures the height of the substrate 50 in, e.g., the central portion of the next crystallization region. The light receiving unit 24 of the measuring optical system 20 converts the detected light into an electrical signal containing the position information and light intensity information by using a CCD camera or the like, and transfers the electrical signal to the gain adjuster 28.

In step 108, the gain adjuster 28 generates a substrate height control signal so as to maximize the optical signal intensity in the measuring light reference position of the light receiving unit 24, and supplies the control signal to the stage driver 34. The stage driver 34 drives the substrate mounting stage in accordance with the control signal, thereby adjusting the height of the substrate 50. In this way, the height of the substrate 50 can be controlled to match the predetermined reference substrate height, i.e., the imaging position of the crystallizing laser beam with a high accuracy of the order of 10 nm.

In step 110, the semiconductor film 53 is melted and crystallized by irradiating the substrate 50 with the crystallizing laser beam having the inverse-peak-pattern light intensity distribution. Since the substrate 50 is set in the imaging position of the crystallizing laser beam, the substrate 50 is irradiated with a laser beam having a predetermined light intensity distribution. This makes it possible to give the semiconductor film 53 a desired temperature distribution, and crystallize the semiconductor film 53 into a film having large crystal grains.

In step 112, it is determined whether the entire surface of the substrate 50 is crystallized. If the entire surface is not crystallized, the process returns to step 104 to move the substrate 50 to the next crystallization position and repeat the crystallization process. If the entire surface is crystallized, the crystallization process is completed.

As described above, this embodiment can control the height of the substrate 50 to a predetermined height within the order of 10 nm. This makes it possible to control the surface of the substrate 50 to coincide with the imaging position of the crystallizing laser beam with a high accuracy of the order of 10 nm. Accordingly, it is possible to repetitively give the semiconductor film 53 to be crystallized a desired temperature distribution with a high accuracy, and stably form a semiconductor film having large crystal grains.

### (Modification)

A modification of the first embodiment is an embodiment in which the reflected light from the interface between the semiconductor film 53 and first cap insulating film 54, e.g., the reflected light R3 shown in FIG. 3A, is used for substrate height control. The reflected light R1 from the surface of the second cap insulating film 55 used in the first embodiment described above has an advantage that the reflected light intensity is highest. However, the tolerance of the film thickness variation of films for use in semiconductor fabrication is generally ±5% to 10%. For example, when the film thickness of the cap insulating films 54 and 55 is 200 nm as described previously, a film thickness variation of ±5% contains a film thickness variation of ±10 nm. If the reflected light from the surface of the second cap insulating film 55 is selected in a case like this, it is difficult to precisely control the actual height of the surface of the semiconductor film 53 of the order of 10 nm.

In this modification, in step 102 of the flowchart shown in FIG. 6, the polarizing element 26 is adjusted to select the reflected light R3 from the interface between the semiconductor film 53 and first cap insulating film 54 as shown in FIG. 7. The intensity of the reflected light R3 is lower than that of the reflected light R1 from the surface of the second cap insulating film 55, but sufficient for use in substrate height control.

After the polarizing element 26 is adjusted to select the reflected light R3, following the same procedure as in the first embodiment of FIG. 6, the reference substrate height is set and the reference position of the measuring light on the light receiving unit 24 is determined in step 102, and the semiconductor film 53 is crystallized by performing steps 104 to 110.

When the reflected light R3 from the interface between the semiconductor film 53 and first cap insulating film 54 is used in substrate height control as described above, the height of the semiconductor film 53 can be controlled to a predetermined height with a high accuracy of the order of 10 nm regardless of the film thicknesses and film thickness variations of the cap insulating films 54 and 55. Accordingly, it is possible to repetitively give the semiconductor film 53 to be crystallized a desired temperature distribution with accuracy higher than that in the first embodiment, and form a semiconductor film having larger crystal grains over the entire surface of the substrate more stably than in the first embodiment.

### Second Embodiment

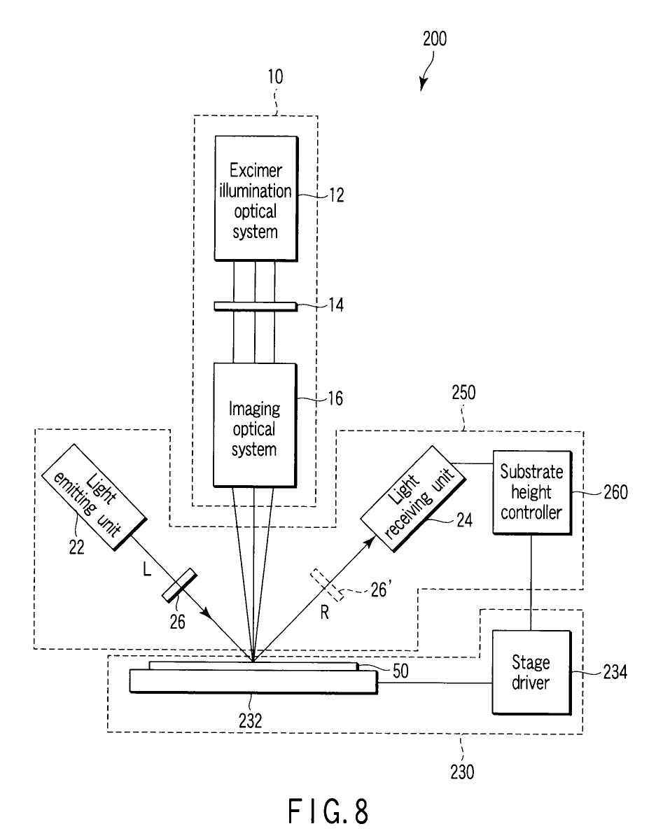

A laser crystallization apparatus according to the second embodiment of the present invention is a crystallization apparatus using a high-accuracy substrate mounting stage having a high-accuracy, height-direction (Z-axis) driving mechanism. FIG. 8 is a view showing an example of a laser crystallization apparatus 200 according to this embodiment. The laser crystallization apparatus 200 comprises a crystallization optical system 10, high-accuracy substrate height measuring system 250, and high-accuracy stage system 230. The crystallization optical system 10 is the same as that of the first embodiment, so a repetitive explanation will be omitted.

The high-accuracy substrate height measuring system 250 uses a substrate height controller 260 instead of the gain adjuster 28 of the laser crystallization apparatus 100 shown in FIG. 1. The substrate height controller 260 will be explained in detail later. A light emitting unit 22, light receiving unit 24, and polarizing element 26 are the same as those of the first embodiment, so an explanation will not be repeated.

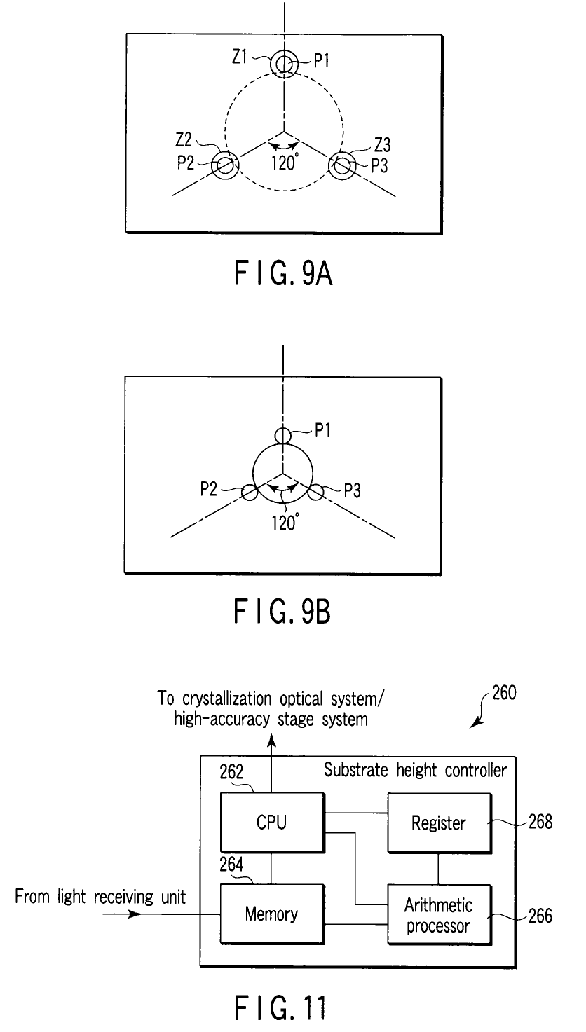

The high-accuracy stage system 230 comprises a high-accuracy substrate mounting stage 232 and stage driver 234. The high-accuracy substrate mounting stage 232 according to this embodiment has Z-axis driving elements for accurately controlling the height of the stage 232. In examples shown in FIGS. 9A and 9B, the high-accuracy substrate mounting stage 232 has three Z-axis driving elements P1 to P3. The way that the substrate mounting stage 232 increases the accuracy of Z-axis driving will be explained below.

To control the height of the substrate mounting stage with a high accuracy of 10 nm, a piezoelectric element is generally used as the driving element for Z-axis driving. It is also possible to use a shaft linear motor. Normally, the height (Z axis) of the stage is controlled by using one driving element.

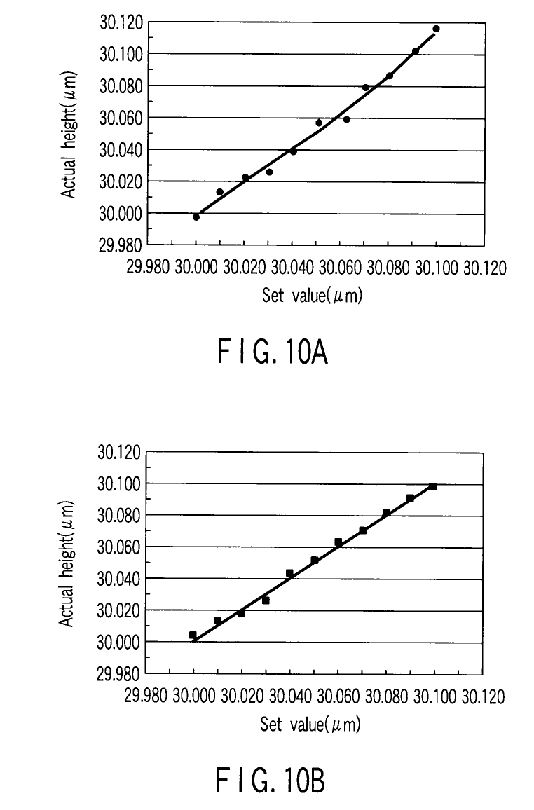

FIG. 10A is a graph showing the relationship between a set value of the substrate height (Z-axis) and the actual substrate height (Z-axis) when controlling the height of the substrate mounting stage by one driving element. In this example shown in FIG. 10A, the actual Z-axis value deviates from a straight line as the Z-axis set value increases. This indicates that one driving element alone cannot maintain the linearity of the Z-axis moving amount of the order of nm because, e.g., the driving shaft deflects when moved.

FIGS. 9A and 9B are views showing examples of the high-accuracy substrate mounting stage 232 using three driving elements according to this embodiment. FIG. 9A is an example in which the piezoelectric elements P1, P2, and P3 respectively drive three independent driving shafts Z1, Z2, and Z3. FIG. 9B is another example in which the three piezoelectric elements P1, P2, and P3 are arranged around one driving shaft Z. The three driving shafts or piezoelectric elements are preferably arranged at equal intervals (120°). The number of the driving elements is not limited to three, and any plural driving elements can perform high-accuracy Z-axis stage driving.

FIG. 10B is a graph showing the relationship between the Z-axis set value and actual Z-axis height when controlling the height of the high-accuracy substrate mounting stage 232 by using a driving element for each of three independent Z-axis driving shafts according to this embodiment as shown in FIG. 9A. When the Z-axis movement is controlled by the three shafts, the high-accuracy substrate mounting stage 232 can be moved with a high linearity over the whole measurement range. The difference between the set value and actual height was ±5 nm or less.

The way that the measurement accuracy is increased by measuring the substrate height a plurality of number of times will now be explained. Although the laser crystallization apparatus 200 is installed in a clean room, there are small dust particles in the room. If a dust particle enters the optical path of the high-accuracy substrate height measuring system 250 during the measurement of the substrate height, abnormality occurs in a measured substrate height signal owing to, e.g., the scattering of light caused by the dust particle. If the substrate height is controlled by using this abnormal signal, it is impossible to achieve any desired substrate height adjustment accuracy. To eliminate an abnormal value like this, therefore, the substrate height is desirably measured a plurality of number of times in controlling the height of one crystallization position. The number of times of measurement is preferably three or more, and more preferably five or more. To accurately control the height of the substrate 50 to be processed with a high reproducibility, a representative value is determined on the basis of these measured values. For example, when measurement is performed five times, maximum and minimum values that are highly likely to contain abnormality during the measurement are excluded from the five measured values, and the mean of the three remaining values is used as a representative value. The median may also be used as a representative value. Alternatively, a representative value can be determined by another method known in this field. When the substrate height is controlled by using the representative value thus determined, the substrate height can be accurately controlled by eliminating the influence of an abnormal value.

The high-accuracy substrate height measuring system 250 used in this embodiment uses the substrate height controller 260 instead of the gain adjuster 28 of the first embodiment (FIG. 1) as described above. The substrate height controller 260 will be explained below with reference to FIG. 11. In an example shown in FIG. 11, the height controller 260 includes a CPU 262, memory 264, arithmetic processor 266, and register 268. The CPU 262 controls the operation of the high-accuracy substrate height measuring system 250. The CPU 262 also controls, e.g., a signal input to the crystallization optical system 10 to emit a crystallizing laser beam, and a signal input to the high-accuracy stage system 230 to adjust the substrate height. The memory 264 stores position information and light intensity information of reflected light supplied from the light receiving unit 24 of the substrate height measuring optical system 250 whenever the substrate height is measured. The memory 264 may also store the reference substrate height and the reference measurement position of the light receiving unit 24, such as obtained in step 102 described previously. In addition, the memory 264 may store information such as the film thicknesses and refractive indices of a base insulating film 52, a semiconductor film 53, and cap insulating films 54 and 55 disposed on the substrate 50. The arithmetic processor 266 obtains a representative value of the deviations of the measured substrate height from the reference substrate height for each crystallization position by using the position information stored in the memory 264. The register 268 stores the representative value obtained by the arithmetic processor 266.

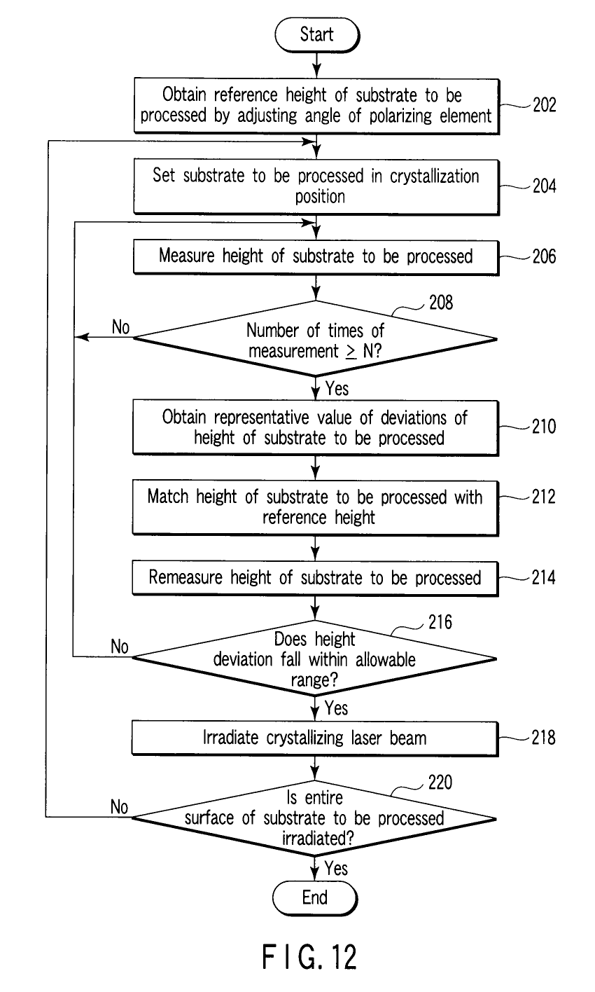

A laser crystallization process using the laser crystallization apparatus 200 including the high-accuracy substrate height measuring system 250 according to this embodiment will be explained below with reference to a flowchart shown in FIG. 12.

In step 202, the polarizing element 26 is adjusted to select a desired reflected light component of a measuring laser beam before crystallization process of the substrate 50, thereby determining a reference substrate height at which the substrate 50 is desirably crystallized and a reference measurement position of the measuring light receiving unit 24 which corresponds to the reference substrate height. A practical method is the same as in step 102 of FIG. 6, so a repetitive explanation will be omitted. The memory 264 of the substrate height controller 260 stores the determined reference substrate height and reference measurement position. The process then advances to step 204.

In step 204, the substrate 50 is mounted on the high-accuracy substrate stage 232 of the laser crystallization apparatus 200 having three independent Z-axis driving shafts as shown in FIG. 10A, and set in a predetermined crystallization position in the plane of the substrate 50 by the high-accuracy stage driver 234. After that, the process advances to step 206.

In step 206, the high-accuracy substrate height measuring optical system 250 measures the height of the substrate 50 in, e.g., the central portion of a region to be crystallized next. The light receiving unit 24 of the measuring optical system 250 converts the detected light into an electrical signal including the position information and light intensity information by using, e.g., a CCD camera, and transfers the signal to the substrate height controller 260. The substrate height controller 260 obtains a deviation from the reference measurement position in the light receiving unit 24 on the basis of the position information, obtains a deviation of the height of the substrate 50 from the reference substrate height corresponding to the obtained deviation from the reference measurement position, and stores the deviations in the memory 264. Then, the process advances to step 208.

In step 208, it is determined whether measurement is successively performed on the crystallization region a predetermined number of times, i.e., N times. If the measurement is not performed the predetermined number of times, the process returns to step 206 to repeat the measurement. If the measurement is performed the predetermined number of times, the process advances to step 210.

In step 210, a representative value of the substrate height deviations in the crystallization region is obtained from the N measured values. As described previously, the representative value can be the mean of the measured values except for maximum and minimum values or median value. The process then advances to step 212.

In step 212, the height controller 260 supplies the substrate height deviation representative value obtained in step 210 to the high-accuracy stage system 230. The stage driver 234 of the high-accuracy stage system 230 drives the high-accuracy substrate mounting stage 232 on the basis of this representative value, thereby controlling the height of the substrate 50 to the predetermined reference height. After that, the process advances to step 214.

In step 214, the measurements executed in steps 206 and 208 are reexecuted in order to check whether the height of the substrate 50 is adjusted to the reference height. Subsequently, a representative value of the substrate height deviations after the substrate height adjustment is obtained. Then, the process advances to step 216.

In step 216, it is determined whether the substrate height deviation obtained in step 214 after the adjustment falls within a predetermined allowable range. The allowable range of the substrate height deviation is, e.g., ±10 nm. However, this range can be changed in accordance with the object of use of the substrate 50 to be crystallized. When the uniformity of the crystal grain size of the crystallized semiconductor film 53 is strictly required, the allowable range can be set as narrow as, e.g., ±5 nm. When the uniformity is not strictly required, the allowable range can be set as broad as, e.g., ±20 nm. If the substrate height deviation falls within the allowable range, the process advances to step 218; if not, the process returns to step 206 to remeasure the substrate height.

Steps 214 and 216 can be omitted as optional steps.

In step 218, the substrate 50 is irradiated with the crystallizing laser beam having an inverse-peak-pattern light intensity distribution, thereby melting and crystallizing the semiconductor film 53. Since the substrate 50 is set at a predetermined reference substrate height, the substrate 50 is irradiated with a laser beam having a predetermined light intensity distribution. This makes it possible to give the semiconductor film 53 a desired temperature distribution, and stably crystallize the semiconductor film 53 with a high reproducibility so that the semiconductor film 53 contains large crystal grains. The process advances to step 220 after that.

In step 220, it is determined whether the entire surface of the substrate 50 is crystallized. If the entire surface is not crystallized, the process returns to step 204 to move the substrate 50 to the next crystallization position and repeat the crystallization process. If the entire surface is crystallized, the crystallization process is completed.

As described above, the height of the substrate 50 is controlled by using the laser crystallization apparatus 200 including the high-accuracy substrate height measuring system 250 and high-accuracy stage system 230 according to this embodiment. When the crystallizing laser beam is irradiated, therefore, the substrate height can be controlled within a predetermined allowable range, e.g., ±10 nm from the reference substrate height. Consequently, it is possible to perform laser crystallization that achieves increased grain size and improved crystal grain size uniformity.

### Third Embodiment

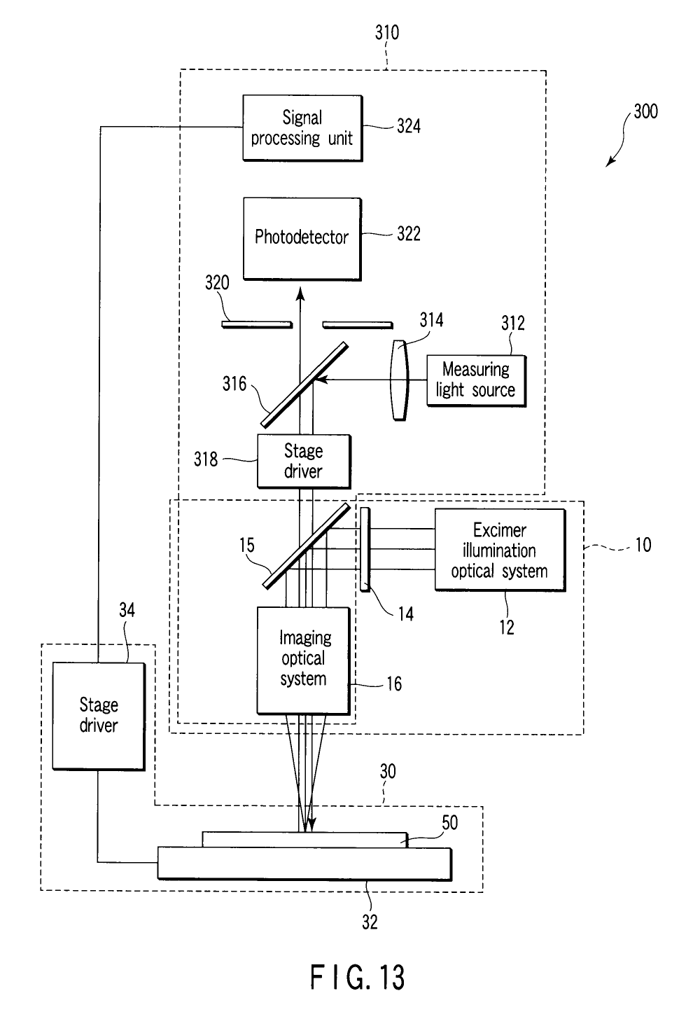

FIG. 13 is a view showing an outline of a laser crystallization apparatus 300 based on the third embodiment of the present invention. The laser crystallization apparatus 300 comprises a crystallization optical system 10 for projecting a phase modulating element 14 in a reduced scale, a substrate height measuring system 310, and a stage system 30. The laser crystallization apparatus 300 has a function of correcting the deviation of the height of a substrate 50 to be processed on the basis of the measurement result from the substrate height measuring system 310. FIG. 13 shows the stage system 30 having the same arrangement as that of the stage system shown in FIG. 1 as an example. However, the stage system 30 may also be replaced with, e.g., the high-accuracy stage system 230 shown in FIG. 8.

The substrate height measuring system 310 has an optical system sharing an imaging optical system 16 of the crystallization optical system 10. Accordingly, a measuring laser beam illuminates a crystallization region on the substrate 50 by the same optical axis as that of a crystallizing laser beam.

In the substrate height measuring system 310, a visible laser beam, e.g., a helium-neon (He—Ne) laser beam, for measuring the imaging position on the substrate 50 emitted from a measuring light source 312, e.g., a visible laser source, is converged by a convergent lens 314 and is directed to the substrate 50 to be processed by a half mirror 316. This measuring visible laser beam illuminates a semiconductor film 53 on the substrate 50 through the imaging optical system 16. Since, however, the imaging optical system 16 is designed for an excimer laser as ultraviolet light, aberration occurs when the measuring visible laser beam enters the imaging optical system 16. A visible light correcting optical system 318, e.g., a visible light correcting lens, for correcting the aberration caused in the imaging optical system 16 by passing through visible light is disposed outside the optical path of the excimer laser beam and between a reflecting mirror 15 and the half mirror 316. The optical system of the substrate height measuring system 310 is thus designed such that the imaging plane of the measuring visible laser beam matches that of the crystallizing excimer laser beam. The reflecting mirror 15 is designed to transmit visible light and reflect the crystallizing excimer laser beam. The semiconductor film 53 on the substrate 50 is set in a position conjugated with the imaging position of the convergent lens 314 with respect to visible light.

The measuring laser beam reflected by the semiconductor film 53 is transmitted through the half mirror 316 after passing through the imaging optical system 16 and visible light correcting lens 318 again, and reaches a photodetector 322 through a pinhole 320. For the measuring laser beam, the pinhole 320 is set in a position conjugated with the imaging position on the side of the substrate 50 with respect to the visible light correcting lens 318 and imaging optical system 16. The size of the pinhole 320 is favorably equal to that of an image of the measuring laser beam on the imaging position on the side of the substrate 50.

The photodetector 322 measures the intensity of the measuring laser beam passing through the pinhole 320, and/or the distortion of the visible light image on the semiconductor film 53. This makes it possible to detect the deviation of the height of the semiconductor film 53 on the substrate 50 from the imaging position of the crystallizing layer beam. As the photodetector 322, it is possible to use, e.g., a two-dimensional CCD imaging device, photodiode, phototransistor, or photomultiplier.

A signal processing unit 324 processes an electrical signal detected and converted by the photodetector 322, thereby obtaining the deviation from the imaging position. To correct this deviation, the signal processing unit 324 supplies a correction signal to the stage system 30. Thus, the signal processing unit 324 can correct the height of a substrate mounting stage 32 via a stage driver 34. As described above, the substrate height measuring system 310 of this embodiment shares the imaging optical system 16 with the crystallizing laser beam. Therefore, it is possible to simultaneously correct the deviation of the imaging position resulting from, e.g., the thermal effect of the imaging optical system 16.

An example of the method of correcting the substrate height by using the substrate height measuring system 310 will now be explained. For example, the height of the semiconductor film 53 is corrected by measuring the intensity of the reflected measuring laser beam from the semiconductor film 53 by the photodetector 322. The measuring laser beam is reflected by the semiconductor film 53, and reaches the photodetector 322 through the pinhole 320 set in the position conjugated with the imaging position on the side of the semiconductor film 53 with respect to the measuring laser beam.

The intensity of the measuring light passing through the pinhole 320 is measured. Since the pinhole 320 is set as described above, the size of the reflected measuring laser beam image on the plane of the pinhole 320 is almost equal to that of the measuring laser beam image on the semiconductor film 53. The size of the measuring laser beam image on the semiconductor film 53 is minimum when the semiconductor film 53 is in the imaging position of the crystallizing laser beam. If the semiconductor film 53 deviates from this imaging position, the measuring laser beam image on the semiconductor film 53 blurs and becomes larger than that when the semiconductor film 53 is in the imaging position. Consequently, the size of the reflected measuring laser beam image on the pinhole plane becomes larger than the pinhole 320. Since the size of the pinhole 320 is equal to that of the measuring laser beam image when the semiconductor film 53 is in the imaging position, the light passing through the pinhole 320 is partially cut. Accordingly, the intensity of the reflected measuring laser beam reaching the photodetector 322 through the pinhole 320 is lower than that when the semiconductor film 53 is in the imaging position.

The height of the substrate mounting stage 32 is corrected to maximize the intensity of the detected reflected light. When the detected light intensity reaches maximum, substrate height correction is terminated, and then the crystallizing excimer laser beam is irradiated.

As described above, the position of the semiconductor film 53 in the Z direction, i.e., the height of the semiconductor film 53 is corrected immediately before pulse emission of the crystallizing excimer laser beam, such that the intensity of the reflected measuring laser beam from the semiconductor film 53 detected by the photodetector 322 is always maximum. In this manner, the imaging position of the crystallizing excimer laser beam on the semiconductor film 53 on the substrate 50 can be corrected so that it is possible to simultaneously correct the imaging position deviation caused by the thermal effect of the imaging optical system 16, and the imaging position deviation caused by, e.g., deflection of the substrate 50.

As has been explained above, the embodiments of the present invention can control the height of the substrate 50 to a predetermined height of the order of 10 nm. This makes it possible to adjust the semiconductor film 53 to be crystallized to the imaging position of the crystallizing laser beam with a high accuracy of the order of 10 nm. Accordingly, it is possible to repetitively give the semiconductor film 53 a desired temperature distribution with a high accuracy, and stably form a semiconductor film having large crystal grains on the entire surface of a large-area substrate.

The present invention is not limited to the embodiments disclosed in this specification, and also applicable to another embodiment without departing from the spirit and scope of the invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A laser crystallization method comprising:
obtaining a first pulse laser beam having an inverse-peak-pattern light intensity distribution by transmitting light through a phase shifter; and
irradiating a thin film disposed on a substrate with the first pulse laser beam, thereby melting and crystallizing the thin film, the method comprising:
selecting a desired one of a plurality of reflected light components of a second laser beam by using a polarizing element disposed on an optical path of the second laser beam when illuminating, with the second laser beam, an irradiation position of the thin film to be irradiated with the first pulse laser beam and detecting the second laser beam reflected by the thin film;
correcting a height of the substrate to a predetermined height by detecting the selected reflected light component of the second laser beam; and
irradiating the first pulse laser beam to the irradiation position of the thin film on the substrate having the corrected height.

2. The method according to claim 1, wherein selecting the reflected light component comprises selecting the desired reflected light component by adjusting a polarizing direction of the second laser beam by rotating the polarizing element.

3. The method according to claim 1, wherein the selected reflected light component is a reflected light component reflected by a surface of the thin film.

4. The method according to claim 1, further comprising:
repetitively detecting the selected reflected light component of the second laser beam a plurality of number of times in succession in the same irradiation position of the thin film; and
determining a representative value of substrate height deviations from a reference substrate height in the irradiation position on the basis of a plurality of detection results.

5. The method according to claim 1, wherein correcting the height comprises correcting the height of the substrate such that light intensity of the selected reflected light component of the second laser beam is maximum in a predetermined detection position.

6. The method according to claim 1, wherein correcting the height comprises correcting the height with an accuracy of 10 nm.

7. The method according to claim 1, wherein an incident angle of the second laser beam is 0° (exclusive) to 75° (inclusive).

8. The method according to claim 1, wherein the thin film includes a cap insulating film, a semiconductor film, and a base insulating film.

9. The method according to claim 8, wherein the selected reflected light component is a reflected light component reflected by an interface between the semiconductor film and the cap insulating film.

10. The method according to claim 1, wherein irradiating the first pulse laser beam is repeated by changing the irradiation position on the thin film.

11. A laser crystallization apparatus comprising a crystallization optical system configured to melt and crystallize an irradiation region of a thin film disposed on a substrate by irradiating the thin film with a first laser beam having an inverse-peak-pattern light intensity distribution, the apparatus comprising:
a substrate height correcting mechanism, the mechanism including:
a light emitting unit disposed outside an optical path of the first laser beam, and configured to emit a second laser beam which illuminates the irradiation region of the thin film to be irradiated with the first laser beam;
a light receiving unit configured to detect the second laser beam reflected by the thin film, and convert the detected second laser beam into an electrical signal; and
a polarizing element disposed on an optical path of the second laser beam and outside the optical path of the first laser beam, and configured to select a desired one of a plurality of reflected light components of the second laser beam by adjusting a polarizing direction.

12. The apparatus according to claim 11, further comprising a stage driver configured to control a height of the substrate.

13. The apparatus according to claim 12, wherein the stage driver controls the height of the substrate with an accuracy of 10 nm.

14. The apparatus according to claim 12, further comprising a gain adjuster configured to adjust intensity of the electrical signal converted by the light receiving unit, and supply a substrate height control signal to the stage driver.

15. The apparatus according to claim 11, wherein the light receiving unit comprises a magnifying lens configured to magnify the reflected light of the second laser beam.

16. The apparatus according to claim 15, wherein the light receiving unit has a positional resolution of 10 nm.

17. A laser crystallization apparatus comprising a crystallization optical system configured to melt and crystallize an irradiation region of a thin film disposed on a substrate by irradiating the thin film with a first laser beam having an inverse-peak-pattern light intensity distribution, the apparatus comprising:
a substrate height measuring mechanism; and
a substrate stage mechanism,
the substrate height measuring mechanism including:
a light emitting unit disposed outside an optical path of the first laser beam, and configured to emit a second laser beam which illuminates the irradiation region of the thin film to be irradiated with the first laser beam;
a light receiving unit configured to detect the second laser beam reflected by the thin film, and convert the detected second laser beam into an electrical signal; and
a polarizing element disposed on an optical path of the second laser beam and outside the optical path of the first laser beam, and configured to select a desired one of a plurality of reflected light components of the second laser beam by adjusting a polarizing direction, and
the substrate stage mechanism including:
a substrate mounting stage independently movable in three directions perpendicular to each other, and including a plurality of driving elements for movement in a height direction; and
a stage driver configured to control the movement of the substrate mounting stage.

18. The apparatus according to claim 17, wherein the substrate mounting stage has a height movement accuracy of 10 nm.

19. The apparatus according to claim 17, wherein the plurality of driving elements are disposed in one-to-one correspondence with height driving shafts independent of each other, and the height driving shafts are arranged at equal intervals on a circumference.

20. The apparatus according to claim 17, wherein the plurality of driving elements are arranged at equal intervals on a circumference of one height driving shaft.
